(19) United States
(12) Patent Application Publication
(10) Pub. No.: US 2016/0329915 A1
(43) Pub. Date: Nov. 10, 2016

(54) APPARATUS AND METHOD FOR ERROR CORRECTION AND PASSIVE OPTICAL NETWORK

(71) Applicant: Futurewei Technologies, Inc., Plano, TX (US)

(72) Inventors: Yuanqiu LUO, Cranbury, NJ (US); Xiang LIU, Marlboro, NJ (US); Frank EFFENBERGER, Colts Neck, NJ (US); Guikai PENG, Shenzhen (CN); Fei YE, Wuhan (CN); Dianbo ZHAO, Shenzhen (CN)

(21) Appl. No.: 15/148,100

(22) Filed: May 6, 2016

Related U.S. Application Data
(60) Provisional application No. 62/158,848, filed on May 8, 2015.

(51) Int. Cl. H03M 13/00; H03M 13/15; H04B 10/27

(52) U.S. Cl. CPC H03M 13/6522; H04B 10/27; H03M 13/1515

(57) ABSTRACT

An error correction method is disclosed, including receiving an input data, processing the input data with a first Forward Error Code (FEC) transformation, processing the input data with a second FEC transformation, and generating an output data including the first transformation and the second transformation.

### CROSS-REFERENCE

This application claims priority to U.S. Provisional Patent Application No. 62/158,848, filed on May 8, 2015, which is hereby incorporated by reference in its entireties.

### BACKGROUND

A passive optical network (PON) is one system for providing network access over the last mile, which is the final portion of a telecommunications network that delivers communication to customers. A PON is a point-to-multipoint (P2MP) network comprised of an optical line terminal (OLT) at a central office (CO), an optical distribution network (ODN), and optical network units (ONUs) at the user premises. PONs may also comprise remote nodes (RNs) located between the OLTs and the ONUs, for instance at the end of a road where multiple customers reside.

In recent years, there are an increasing number of PON access customers. In a PON system, some ONUs or customers may be located closer to an OLT, while other ONUs or customers may be located further away from the OLT. As such, some links may be regular links requiring a class nominal 2 (N2) link budget, while other links may be extended links or enhanced links requiring a class extended 1 (E1) link budget, a class extended 2 (E2) link budget, or even beyond class E1 and E2 link budgets. Link budgets refer to the gains and losses from a transmitter, through a transmission medium and to a receiver. Consequently, a PON system may be required to provide distinct links to ONUs, where a link budget is specifically designed for a transmitter and a receiver pair over each distinct link.

### SUMMARY

Apparatus and methods for error correction are disclosed to provide flexible link budget according to different ONUs.

In one embodiment, the disclosure includes an error correction method, comprising receiving an input data; processing the input data with a first Forward Error Code (FEC) transformation; processing the input data with a second FEC transformation; and generating an output data including the first transformation and the second transformation.

In one aspect, wherein the first and the second FEC transformations comprise FEC encoding or FEC decoding transformations.

In another aspect, wherein the first FEC transformation comprises a regular FEC (rFEC) transformation.

In another aspect, wherein the second FEC transformation comprises an enhanced FEC (eFEC) transformation.

In another aspect, with the first FEC transformation and the second FEC transformation comprising a concatenated processing.

In another aspect, with the first FEC transformation and the second FEC transformation comprising a concatenated processing and with each data block being transformed by both the first FEC transformation and the second FEC transformation.

In another aspect, with the first FEC transformation and the second FEC transformation comprising a parallel processing.

In another aspect, with the first FEC transformation and the second FEC transformation comprising a parallel processing and with first data blocks transformed by the first FEC transformation being interleaved with second data blocks transformed by the second FEC transformation.

In another aspect, wherein the first FEC transformation and the second FEC transformation are based on a link condition.

In another aspect, the method further comprises processing the input data with at least a third FEC transformation.

In another embodiment, the disclosure includes a network device comprising a transceiver configured to receive an input data; and a processor coupled to the transceiver and configured to process the input data with a first Forward Error Code (FEC) transformation, process the input data with a second FEC transformation, and generate an output data including the first transformation and the second transformation.

In one aspect, wherein the first and second FEC transformations comprise FEC encoding or FEC decoding transformations.

In another aspect, wherein the first FEC transformation comprises a regular FEC (rFEC) transformation.

In another aspect, wherein the second FEC transformation comprises an enhanced

In another aspect, wherein the first FEC transformation and the second FEC transformation comprise a concatenated processing.

In another aspect, with the first FEC transformation and the second FEC transformation comprising a concatenated processing and with each data block being transformed by both the first FEC transformation and the second FEC transformation.

In another aspect, wherein the first FEC transformation and the second FEC transformation comprise a parallel processing.

In another aspect, with the first FEC transformation and the second FEC transformation comprising a parallel processing and with first data blocks transformed by the first FEC transformation being interleaved with second data blocks transformed by the second FEC transformation.

In another aspect, wherein the first FEC transformation and the second FEC transformation are based on a link condition.

In another aspect, wherein the processor is configured to process the input data with at least a third FEC transformation.

In third embodiment, the disclosure includes a passive optical network, comprising a first network device, configured to generate an output data by encoding an input data with a first Forward Error Code (FEC) and with a second FEC; and send the output data to a second network device; and the second network device coupled to the first network device and configured to obtain the input data by decoding the output data with the first FEC and the second FEC.

In one aspect, with the first network device comprising an optical line terminal, and optical network unit, or an optical network terminal.

These and other features will be more clearly understood from the following detailed description taken in conjunction with the accompanying drawings and claims.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 is a schematic diagram of an embodiment of a PON.

FIG. 2 illustrates a concatenated or serial FEC transformation processing to an embodiment.

FIG. 3 illustrates a concatenated FEC transformation processing according to another embodiment.

FIG. 4 illustrates a parallel FEC transformation processing according to an embodiment.

FIG. 5 illustrates a parallel FEC transformation processing according to an embodiment.

FIG. 6 is a schematic diagram of an embodiment of a PON.

FIG. 7 is a flowchart of an embodiment of a method for performing concatenated FEC encoding.

FIG. 8 is a flowchart of an embodiment of a method for performing concatenated FEC decoding.

FIG. 9 is a schematic diagram of an embodiment of a parallel FEC encoding scheme.

FIG. 10 is a schematic diagram of an embodiment of a parallel FEC decoding scheme.

FIG. 11 is a schematic diagram illustrating an embodiment of a method for performing parallel FEC encoding.

FIG. 12 is a schematic diagram illustrating an embodiment of a method for performing parallel FEC decoding.

FIG. 13 is a schematic diagram of an embodiment of a network element (NE).

### DETAILED DESCRIPTION

It should be understood at the outset that, although illustrative implementations of one or more embodiments are provided below, the disclosed systems and/or methods may be implemented using any number of techniques, whether currently known or in existence. The disclosure should in no way be limited to the illustrative implementations, drawings, and techniques illustrated below, including the exemplary designs and implementations illustrated and described herein, but may be modified within the scope of the appended claims along with their full scope of equivalents.

One approach to providing distinct links to ONUs in a PON is to reuse the same type of low-cost PON optics at all the ONUs and employ link budget improvement methods or algorithms to meet the higher link budgets required by the ONUs that are located further away from an optical line terminal (OLT) that distributes signals to the ONUs. A class nominal 2 (N2) link may operate at about 31 decibel (dB) signal-to-noise ratio (SNR), a class extended 1 (E1) link may operate at about 33 dB SNR, and a class extended 2 (E2) link may operate at about 35 dB SNR. Thus, an ONU that comprises N2 type PON optics, may operate with an E1 type or an E2 type link budget through link budget improvement methods. Some examples of link budget improvement methods may include rate reduction and FEC gain, for example.

FEC transformations are widely used in PONs for controlling errors in data transmission. FEC transformations add redundancy to transmitted information, thus enabling receivers to detect and correct a certain amount of errors in received signals without data retransmissions. Depending on the specific FEC codes/transformations that are employed, FEC may increase a PON link budget by about 1 dB to about 4 dB. Thus, when employing FEC, a PON may support a higher bit rate, a longer reach (e.g., longer distances between an OLT and ONUs), and/or a higher number of splits per single PON port.

Currently, FEC encoding/decoding is employed in PONs. For example, International Telecommunication Union-Telecommunication Standardization Sector (ITU-T) Recommendation document G.984.3 specifies a Reed-Solomon code, RS(255, 239), as the gigabit-PON (GPON) FEC code. ITU-T Recommendation document G.987.3 specifies RS(248, 216) as the downstream FEC code and RS(248, 232) as the upstream FEC code. The above FEC examples are considered to be “regular” FEC coding techniques (i.e., rFEC). Downstream refers to the transmission direction from an OLT to ONUs. Upstream refers to the transmission direction from ONUs to an OLT. ITU-T Recommendation document G.989.3 specifies FEC codes based on line rates, for example, RS(248, 232) is specified for 2.5 gigabit (G) links and RS(248, 216) is specified for 10 G links. All of these standards are incorporated herein by reference.

However, in most cases, the FEC codes that are required for link budget improvement are different from the FEC codes specified by commonly employed PON standards (i.e., regular FEC codes/coding), such as the ITU-T standards described above. As such, the design of PON-compatible FEC may be a key for providing distinct optical links in PONs. However, a transmitter may not directly apply a new FEC code to a data frame without additional processing, since a standard receiver at the receiving end of the link may not be able to correctly decode the FEC codewords in the received signal without knowledge of the new FEC code. Thus, mechanisms for incorporating FEC to support coexistence of distinct links may be important for the designs of PONs.

Disclosed herein are embodiments for providing link performance improvements in PONs by employing an FEC scheme that comprises multiple FEC codes, generated by multiple FEC coders. The FEC coders may be a combination of regular FEC (rFEC) coders defined by PON standards, such as the ITU-T standards described above, and enhanced FEC (eFEC) coders designed for enhanced performance and/or extended reach.

eFEC refers to use codewords that are different from rFEC. For example, when the rFEC is RS(248,232), the eFEC could have many designs for enhanced link performance, such as RS (209, 187). Enhanced FEC in some examples comprises an FEC scheme that offers better gain than regular FEC.

The eFEC coders may be implemented as software components. Thus, ONUs comprising standard PON low-cost optics and hardware may be upgraded to support eFEC via software upgrade, without hardware modifications. Further, the eFEC coders may support several eFEC codes and may be configured to adapt to link conditions by selecting a suitable eFEC code in some examples. Therefore, the disclosed embodiments are suitable for providing a distinct optical link for each ONU in a PON.

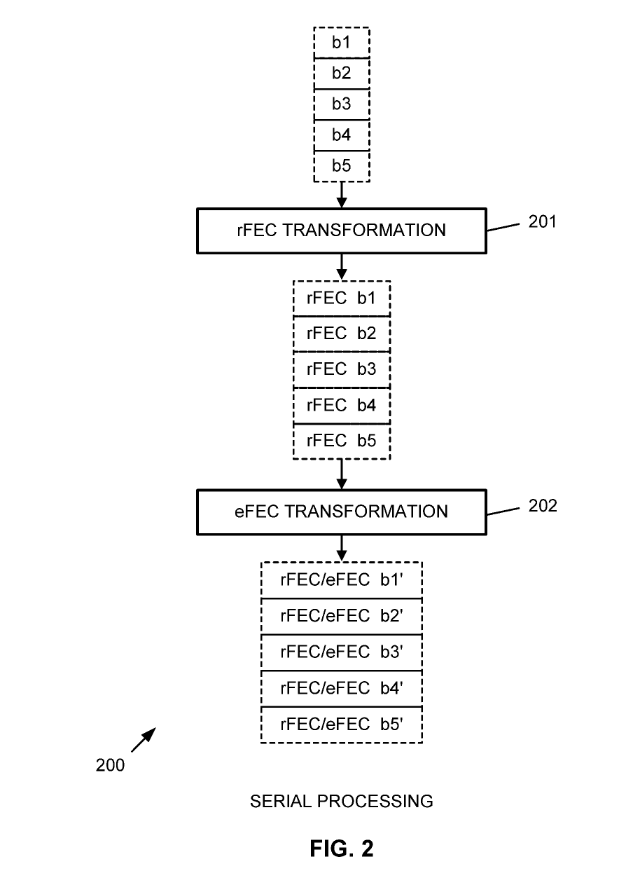

For example, a transmitter may apply a first FEC encoding scheme, such as an eFEC scheme, with an FEC 1 code, followed by a second FEC encoding scheme, such as an rFEC scheme, with an FEC 2 code (see FIG. 2, for example). The first FEC encoding scheme may encode data in blocks of k2 bits, for example. The second FEC scheme may encode data in blocks of k1 bits, where k1 and k2 are positive integers. The k1 and k2 values may be the same or different. Thus, a receiver may decode a received signal according to the FEC 2 code, followed by the FEC 1 code.

In a second embodiment, a PON may employ a parallel FEC coding/decoding scheme. For example, a transmitter may divide a PON transmission convergence (TC) frame into a plurality of TC blocks and encode each TC block according to an FEC code, which may be an rFEC code or an eFEC code. The size of each TC block could be same or different. The size of each block could be different based on link conditions. The size of each block could be different based on coder characteristics. The coder characteristics could be defined by coder speed, for example. The coder includes encoder and decoder.

Subsequently, each FEC-encoded block may be modulated or demodulated, as needed. Each FEC-encoded block may be modulated with the same modulation scheme or with differing different modulation schemes. An OOK modulation is given as example, but it should be understood that other modulations could be used. For instance, the modulation can comprise pulse amplitude modulation (PAM), Non-Return Zero (NRZ) modulation, duobinary modulation, quadrature phase shift keying (QPSK), and so on. The disclosed embodiments provide various mechanisms to avoid incompatibilities when employing standard ONUs implementing standard PON FEC and enhanced ONUs implementing enhanced FEC in the same PON.

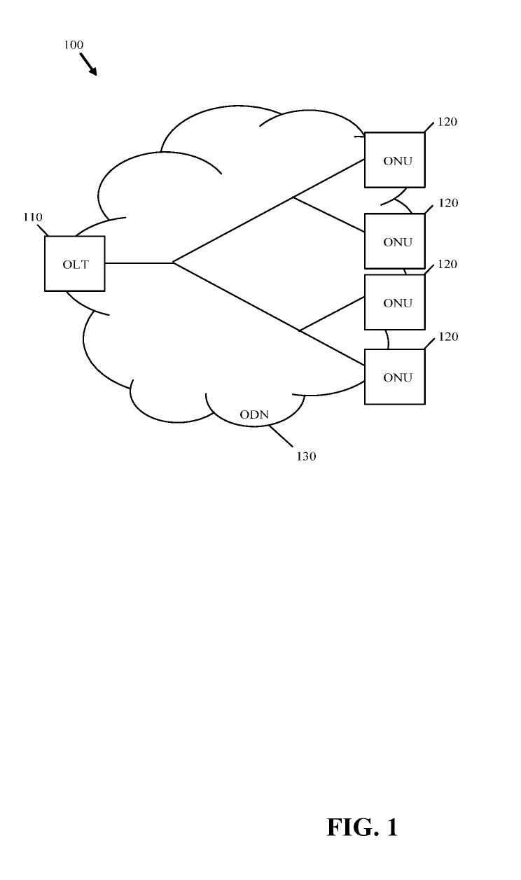

FIG. 1 is a schematic diagram of a PON 100 in one example. The PON 100 comprises an OLT 110, a plurality of ONUs 120, and an optical distribution network (ODN) 130, which may be coupled to the OLT 110 and the ONUs 120. The PON 100 may be a communications network that does not require any active components to distribute data between the OLT 110 and the ONUs 120. Instead, the PON 100 may use the passive optical components in the ODN 130 to distribute data between the OLT 110 and the ONUs 120.

In an embodiment, the PON 100 may be a Next Generation Access (NGA) system, such as a 10 Gbps GPON (XGPON), which may have a downstream bandwidth of about 10 Gbps and an upstream bandwidth of at least about 2.5 Gbps. Alternatively, the PON 100 may be any Ethernet based network, such as an Ethernet PON (EPON) defined by the Institute of Electrical and Electronics Engineers (IEEE) 802.3ah standard, a 10 Gigabit EPON as defined by the IEEE 802.3av standard, an asynchronous transfer mode PON (APON), a broadband PON (BPON) defined by ITU-T G.983 standard, a GPON defined by the ITU-T G.984 standard, or a wavelength division multiplexed (WDM) PON (WPON).

In an embodiment, the OLT 110 may be any device that is configured to communicate with the ONUs 120 and another network (not shown). Specifically, the OLT 110 may act as an intermediary between the other network and the ONUs 120. For instance, the OLT 110 may receive data from another network and forward the data to the ONUs 120, and likewise may forward data from the ONUs 120 to the other network. Although the specific configuration of the OLT 110 may vary depending on the type of PON 100, in an embodiment, the OLT 110 may comprise a transmitter and a receiver. When the other network is using a network protocol that is different from the PON protocol used in the PON 100, such as Ethernet or Synchronous Optical Networking/Synchronous Digital Hierarchy (SONET/SDH), the OLT 110 may comprise a converter that converts the network protocol into the PON protocol. The OLT 110 converter may also convert the PON protocol into the network protocol. The OLT 110 may be typically located at a central location, such as a central office, but may be located at other locations as well.

In an embodiment, the ODN 130 may be a data distribution system, which may comprise optical fiber cables, couplers, splitters, distributors, and/or other equipment. In an embodiment, the optical fiber cables, couplers, splitters, distributors, and/or other equipment may be passive optical components. Specifically, the optical fiber cables, couplers, splitters, distributors, and/or other equipment may be components that do not require any power to distribute data signals between the OLT 110 and the ONUs 120. Alternatively, the ODN 130 may comprise one or a plurality of active components, such as optical amplifiers. The ODN 130 may typically extend from the OLT 110 to the ONUs 120 in a branching configuration as shown in FIG. 1, but may be alternatively configured in any other point-to-multi-point configuration.

In an embodiment, the ONUs 120 comprise devices that are configured to communicate with the OLT 110 and a customer or user (not shown). Specifically, the ONUs 120 may act as an intermediary between the OLT 110 and the customer. For instance, the ONUs 120 forward data from the OLT 110 to the customer, and forward data from the customer to the OLT 110. Although the specific configuration of the ONUs 120 may vary depending on the type of PON 100, in an embodiment, the ONUs 120 may comprise optical transmitters configured to send optical signals to the OLT 110 and optical receivers configured to receive optical signals from the OLT 110. Additionally, the ONUs 120 may comprise converters that convert optical signals into electrical signals for customers, such as signals in the Ethernet or asynchronous transfer mode (ATM) protocol, and a second transmitter and/or receiver that may send and/or receive the electrical signals to/from a customer device. In some embodiments, ONUs 120 and optical network terminals (ONTs) are similar, and thus the terms are used interchangeably herein. The ONUs 120 may be typically located at distributed locations, such as the customer premises, but may be located at other locations as well.

FIG. 2 illustrates a concatenated or serial FEC transformation processing 200 according to an embodiment. The concatenated FEC transformation processing 200 includes a rFEC transformation 201 that transforms an input data, comprising five data elements or data blocks (b1-b5). The rFEC transformation 201 transforms the data into rFEC-transformed data elements or data blocks (rFEC b1-rFEC b5). The rFEC-transformed data elements or data blocks (rFEC b1-rFEC b5) are subsequently inputted into an eFEC transformation 202. The eFEC transformation 202 transforms the rFEC-transformed data elements or data blocks (rFEC b1-rFEC b5) into eFEC-transformed data elements or blocks (rFEC/eFEC b1′-rFEC/eFEC b5′).

The concatenated FEC transformation processing 200 implements an error correction method comprising receiving an input data, processing the input data with a first Forward Error Code (FEC) transformation, processing the input data with a second FEC transformation, and generating an output data including the first transformation and the second transformation. The first FEC transformation and the second FEC transformation in this example comprise a concatenated processing. Each data block is transformed by both the first FEC transformation and the second FEC transformation in this example.

The first and second FEC transformations comprise FEC encoding or FEC decoding transformations. In some examples, the first FEC transformation comprises a regular FEC (rFEC) transformation and the second FEC transformation comprises an enhanced FEC (eFEC) transformation.

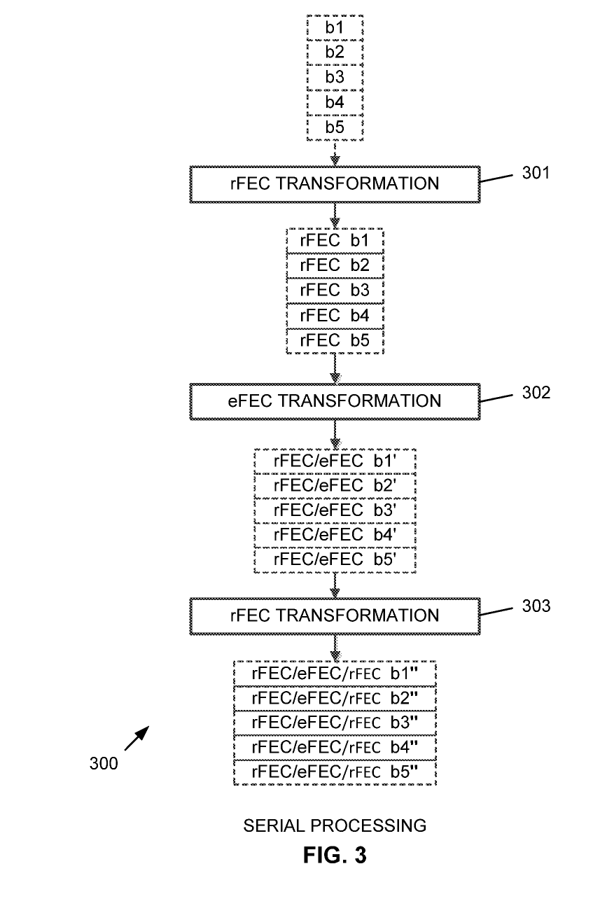

The concatenated FEC transformation processing 200 in some examples further comprises processing the input data with at least a third FEC transformation (see FIG. 3 and the accompanying discussion below).

In some examples, the first FEC transformation and the second FEC transformation are based on a link condition. For example, when an associated link is experiencing high traffic loads or significant error conditions, then the concatenated FEC transformation processing 200 can be selected or controlled to improve the link condition. In some examples, the concatenated FEC transformation processing 200 can increase the use of the eFEC transformations based on the link condition, where the eFEC transformations offer faster FEC processing. Alternatively, or in addition, the eFEC transformations in other examples results in a lower error rate. The use of eFEC transformations therefore can be selected or controlled to improve the link condition.

FIG. 3 illustrates a concatenated FEC transformation processing 300 according to another embodiment. The concatenated FEC transformation processing 300 includes a rFEC transformation 301, followed by an eFEC transformation 302, followed by another rFEC transformation 303. As a result, two rFEC transformations are applied to the data elements or data blocks in this example, along with a single eFEC transformation. The order shown is rFEC-eFEC-rFEC, but it should be understood that any desired order of the transformations can be employed. Further, any number of serial rFEC and eFEC transformations can be employed.

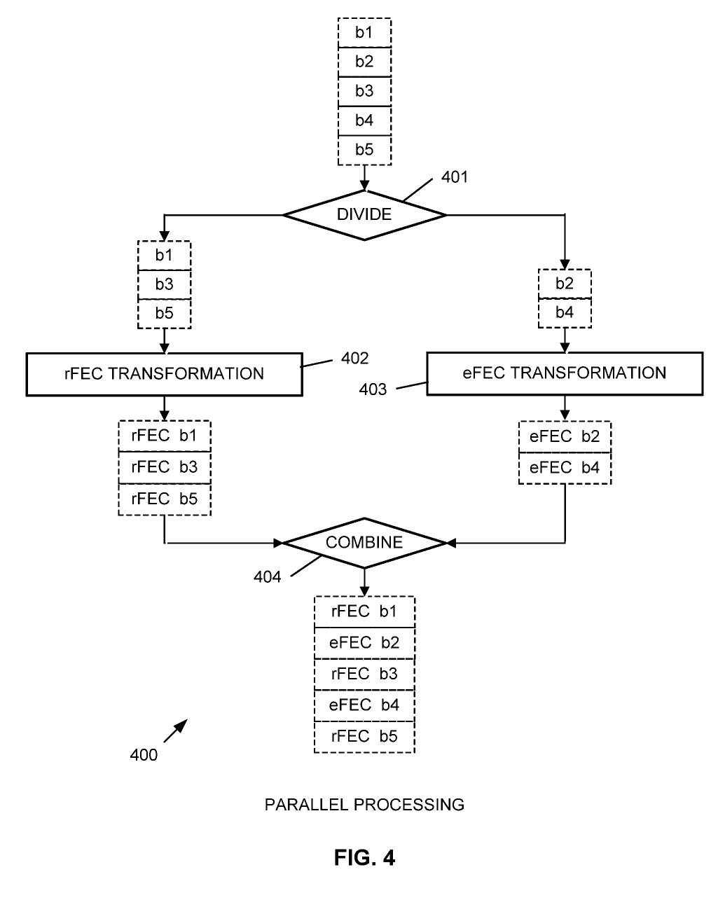

FIG. 4 illustrates a parallel FEC transformation processing 400 according to an embodiment. The parallel FEC transformation processing 400 includes a divide element 401 that divides inputted data into two parallel processing branches. In a first parallel processing branch, a rFEC transformation 402 receives and transforms the data elements or data blocks b1, b3, and b5, generating the rFEC-transformed data elements or blocks (rFEC b1, rFEC b3, rFEC b5). In a second parallel processing branch, an eFEC transformation 403 receives and transforms the data elements or data blocks b2 and b4, generating the eFEC-transformed data elements or blocks (eFEC b2, eFEC b4). The rFEC-transformed data elements or blocks (rFEC b1, rFEC b3, rFEC b5) and the eFEC-transformed data elements or blocks (eFEC b2, eFEC b4) are subsequently inputted into a combine element 404. The combine element 404 combines the outputs of the two processing branches into an output data (rFEC b1, eFEC b2, rFEC b3, eFEC b4, rFEC b5) in this example.

In some embodiments, the combine element 404 combines the data elements or data blocks into an original order, as shown. However, the combine element 404 can alternatively combine the two data branches in any desired order.

The parallel FEC transformation processing 400 implements an error correction method comprising receiving an input data, processing the input data with a first Forward Error Code (FEC) transformation, processing the input data with a second FEC transformation, and generating an output data including the first transformation and the second transformation. The first FEC transformation and the second FEC transformation in this example comprise a parallel processing. First data blocks transformed by the first FEC transformation are interleaved with second data blocks transformed by the second FEC transformation.

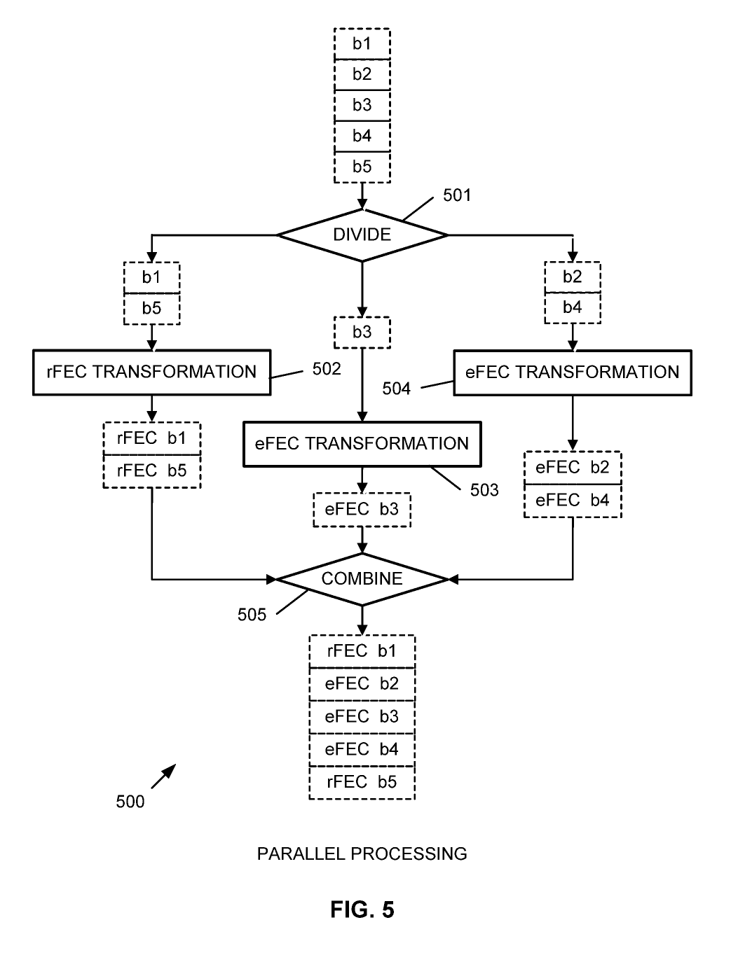

It can be seen that in the parallel processing, each data element or data block is transformed once in the example given. However, data elements or data blocks can be transformed multiple times in a processing branch. Further, more than two processing branches can be employed (see FIG. 5 and the discussion below). In another embodiment, an individual processing branch can comprise a hybrid processing branch, including both rFEC and eFEC transformations, in any desired order and in any desired number.

The first and second FEC transformations comprise FEC encoding or FEC decoding transformations. In some examples, the first FEC transformation comprises a regular FEC (rFEC) transformation and the second FEC transformation comprises an enhanced FEC (eFEC) transformation.

The parallel FEC transformation processing 400 in some examples further comprises processing the input data with at least a third FEC transformation (see FIG. 5 and the accompanying discussion below).

In some examples, the first FEC transformation and the second FEC transformation are based on a link condition. For example, when an associated link is experiencing high traffic loads or significant error conditions, then the parallel FEC transformation processing 400 can be selected or controlled to improve the link condition. In some examples, the parallel FEC transformation processing 400 can increase the use of the eFEC transformations based on the link condition, where the eFEC transformations offer faster FEC processing. Alternatively, or in addition, the eFEC transformations in other examples results in a lower error rate. The use of eFEC transformations therefore can be selected or controlled to improve the link condition.

FIG. 5 illustrates a parallel FEC transformation processing 500 according to an embodiment. The parallel FEC transformation processing 500 includes a divide element 501 that divides inputted data into three parallel processing branches in this example. In a first parallel processing branch, a rFEC transformation 502 receives and transforms the data elements or data blocks b1 and b5, generating the rFEC-transformed data elements or blocks (rFEC b1, rFEC b5). In a second parallel processing branch, an eFEC transformation 503 receives and transforms the data element or data block b3, generating the eFEC-transformed data element or data block (eFEC b3). In a third parallel processing branch, an eFEC transformation 504 receives and transforms the data elements or data blocks b2 and b4, generating the eFEC-transformed data elements or blocks (eFEC b2, eFEC b4). The rFEC-transformed data elements or data blocks (rFEC b1, rFEC b5) and the eFEC-transformed data elements or data blocks (eFEC b3) and (eFEC b2, eFEC b4) are subsequently inputted into a combine element 505. The combine element 505 combines the outputs of the three processing branches into an output data (rFEC b1, eFEC b2, eFEC b3, eFEC b4, rFEC b5) in this example.

It can be seen that in the parallel FEC transformation processing 500, each data element or data block is transformed once in the example given, where more than two processing branches are employed. However, data elements or data blocks can be transformed multiple times in a processing branch. In another embodiment (not shown), an individual processing branch can comprise a hybrid processing branch, including both rFEC and eFEC transformations, in any desired order and in any desired number.

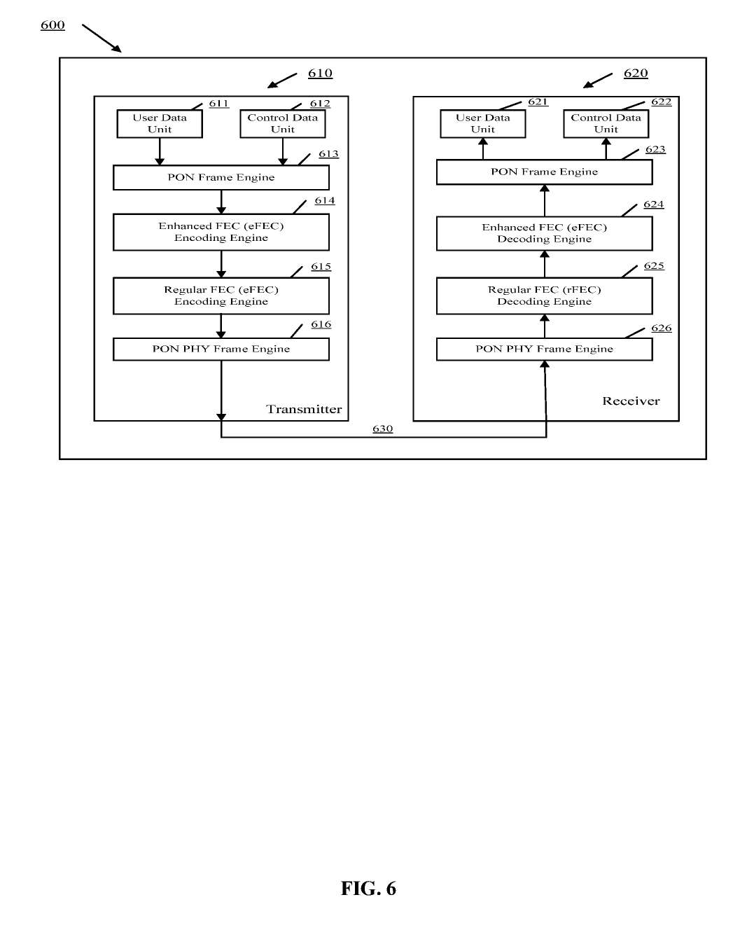

FIG. 6 is a schematic diagram of an embodiment of a PON 600. The PON 600 may correspond to a portion of the PON 100. The PON 600 employs a concatenated FEC coding scheme. The PON 600 comprises a transmitter 610 and a receiver 620 communicatively coupled via an optical link 630, which may comprise optical fiber cables, splitters, couplers, distributors, and/or other equipment. The optical link 630 may be a N2 type link, an E1 type link, an E2 type link, or any other type of optical link suitable for data transmission. In an embodiment, the transmitter 610 may correspond to a transmitter at an OLT, such as the OLT 610, and the receiver 620 may correspond to a receiver at an ONU, such as the ONU 620. In another embodiment, the transmitter 610 may correspond to a transmitter at an ONU and the receiver 620 may correspond to a receiver at an OLT.

The transmitter 610 comprises a user data unit 611, a control data unit 612, a PON TC frame engine 613, an eFEC encoding engine 614, an rFEC encoding engine 615, and a PON physical layer (PHY) frame engine 616. The PON TC frame engine 613 is coupled to the user data unit 611 and the control data unit 612. The PON TC frame engine 613 is configured to receive user data from the user data unit 611, receive control data from the control data unit 612, and generate standard PON TC frames from the received user data and control data. The eFEC encoding engine 614 is coupled to the PON TC frame engine 613. The eFEC encoding engine 614 is configured to perform performance enhancements, such as eFEC encoding, on the TC frames. For example, the eFEC encoding engine 614 may generate enhanced FEC codewords from the TC frames. The rFEC encoding engine 615 is coupled to the eFEC encoding engine 614 and configured to perform FEC encoding on the eFEC-encoded frames according to PON standards. The PON PHY frame engine 616 is coupled to the rFEC encoding engine 615 and configured to generate standard PON PHY frames based on the rFEC-encoded frames. The transmitter 610 may further comprise an optical and/or electrical frontend configured to convert the PON PHY frames into electrical signals, and subsequently into an optical signal, and transmit the optical signal over the link 630. It should be noted that the PON TC frame engine 613, the rFEC encoding engine 615, and the PON PHY frame engine 616 perform standardized PON operations, whereas rFEC encoding engine 615 performs link budget improvement operations that are not standard PON operations.

The receiver 620 comprises a user data unit 621, a control data unit 622, a PON TC frame engine 623, an eFEC decoding engine 624, an rFEC decoding engine 625, and a PON PHY frame engine 626. The receiver 620 may further comprise an optical and/or electrical frontend configured to receive the optical signal transmitted over the link 630 and convert the optical signal into electrical signal. For example, the PON PHY frame engine 626 may be coupled to the optical and/or electrical frontend. The PON PHY frame engine 626 is configured to re-assemble the PON PHY frames from the received signal. The rFEC decoding engine 625 is coupled to the PON PHY frame engine 626 and configured to perform rFEC decoding on the rFEC codewords carried in the PON PHY frames. The eFEC decoding engine 624 is coupled to the rFEC decoding engine 625 and configured to perform eFEC. For example, the eFEC decoding engine 624 decodes the eFEC codewords generated by the eFEC encoding engine 614 at the transmitter 610. The improved performance is achieved via the enhanced FEC error detection and correction. The PON TC frame engine 623 is coupled to the eFEC decoding engine 624 and configured to reassemble eFEC-decoded frames into standard PON TC frames and separate the standard PON TC frames into user data portions and control data portions. Subsequently, the PON TC frame engine 623 provides the user data portions of the TC frames to the user data unit 621 and the control data portions of the TC frames to the control data unit 622. It should be noted that the PON TC frame engine 623, the rFEC decoding engine 625, and the PON PHY frame engine 626 perform standardized PON operations, whereas the rFEC decoding engine 625 performs link budget improvement operations that are not standard PON operations.

In an embodiment, the eFEC encoding engine 614 and the eFEC decoding engine 624 are software components, which may provide more flexibility when compared to hardware implementation engines and optical frontends composed from hardware components. By implementing the eFEC encoding engine 614 and the eFEC decoding engine 624 as software components, when a customer requires a distinct link, the PON may upgrade the sender of the link with an eFEC encoding engine 614 and the receiver of the link with an eFEC decoding engine 624 e.g., by software downloading. By upgrading the sender and the receiver via software download, replacement of optics and hardware may be avoided. As such, the same ONU equipment may be used for different customers and enhanced link performance may be achieved by configuring and/or enabling eFEC settings.

In another embodiment, the eFEC encoding engine 614 and the eFEC decoding engine 624 may adapt to link conditions and/or link budget requirements. The eFEC encoding engine 614 and the eFEC decoding engine 624 may be built with several FEC codes, for example, a K1 code and a K2 code. K1 code may meet a link budget of J1 and K2 code may meet a link budget of J2. Thus, the eFEC encoding engine 614 and the eFEC decoding engine 624 may be configured to adapt to the different link budgets by employing an FEC code corresponding to the required link budget.

In another embodiment, further improvements may be obtained from a joint design between eFEC and rFEC. For example, a joint FEC design may be employed for the eFEC encoding engine 614 and the rFEC encoding engine 615 and/or for the eFEC decoding engine 624 and the rFEC decoding engine 625. As an example, eFEC codewords may be in units of X bytes and rFEC codewords may be in units of Y bytes. Thus, a joint FEC engine may configure data processing segments in units of Z bytes, where A3 is the least common multiple (LCM) of X and Y.

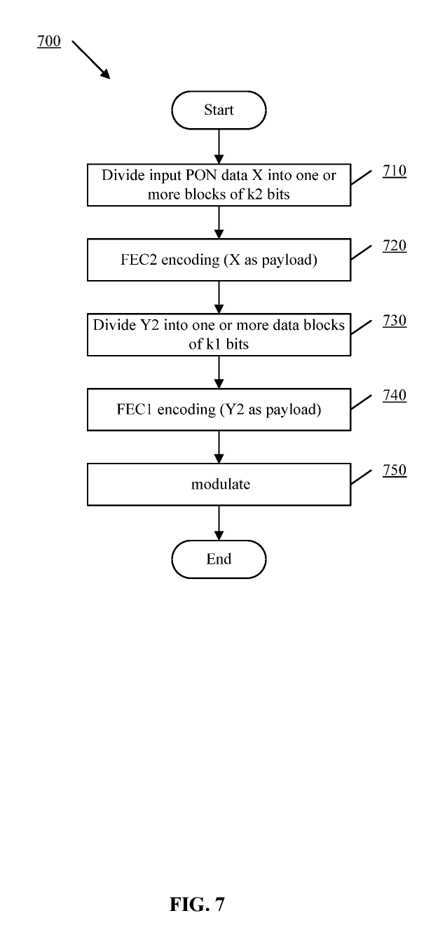

FIG. 7 is a flowchart of an embodiment of a method 700 for performing concatenated FEC encoding (i.e., serial processing). The method 700 is implemented by a transmitter, such as the transmitter 710, in a PON, such as the PON 700. The method 700 is implemented when generating PON PHY frames for transmission. At step 710, input PON data, denoted as X, is divided into one or more blocks of k2 size. At step 720, each block of k2 size is encoded by employing an FEC2 code (n2, k2), where n2 represents FEC2 codeword size. For example, each block of k2 size is encoded into an FEC2 codeword of n2 size, where n2 is greater than k2. The FEC2 codewords produced by the FEC2 code may be re-combined to form a data block Y2. At step 730, the data block Y2 is divided into one or more blocks, each with a block size of k1. At step 740, each block of k1 size is encoded by employing a FEC1 code (n1, k1), where n1 represents the size of the FEC1 codeword. For example, each block of k1 size is encoded into an FEC1 codeword of n1 size, where n1 is greater than k1. The FEC1 codewords produced by the FEC1 code may form a data bit sequence Y1. At step 750, the data bit sequence Y1 is modulated, such as being modulated according to an on-off keying (OOK) scheme. The OOK scheme is given merely as an example. Other modulations could be used, such as pulse amplitude modulation (PAM), quadrature amplitude modulation (QAM), quadrature phase shift keying (QPSK), non-return zero (NRZ), and so on.

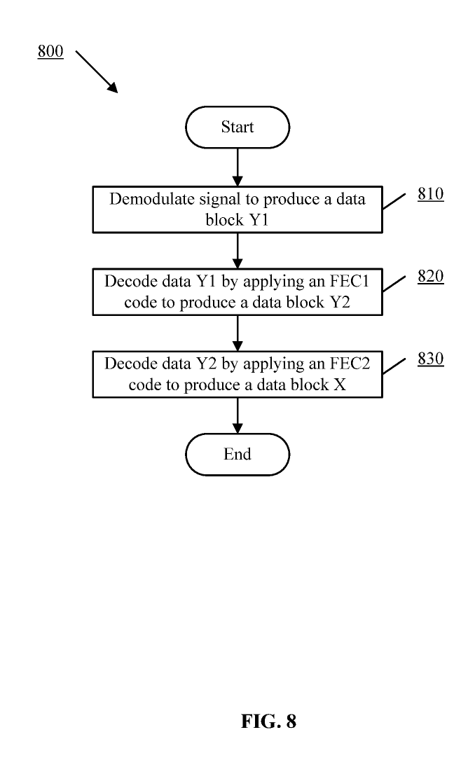

FIG. 8 is a flowchart of another embodiment of a method 800 for performing concatenated FEC decoding. The method 800 is implemented by a receiver, such as the receiver 820, in a PON, such as the PON 800. The method 800 begins when the receiver receives a modulated signal transmitted by a transmitter similar to the transmitter 710. For example, the transmitter may generate the modulated signal by employing the method 800. The modulation could comprise a OOK modulation scheme, but other modulation could be used as well, for instance, PAM, QAM, QPSK, NRZ and so on. At step 810, the received modulated signal is demodulated into a data block Y1. At step 820, the data block Y1 is decoded by applying a FEC1 code to produce a data block Y2. At step 830, the data block Y2 is decoded by applying a FEC2 code to produce a data block X, which is the input data payload transmitted by the transmitter. It should be noted that the FEC1 code and the FEC2 code may be pre-determined between the transmitter and the receiver, and may be employed by both the transmitter and the receiver.

In an embodiment, FEC1 may be a FEC as specified by a PON standard, such as the ITU-T standards described above or any other PON standards. In such an embodiment, standard ONUs may decode downstream PON data according to the PON standard, and thus there is no implementation incompatibility. ONUs that are configured with eFEC, such as the eFEC decoding engine 624, may perform further decoding by applying FEC2 decoding to achieve link performance improvement.

In another embodiment, in order to avoid limiting the overall decoding performance by FEC1, two approaches may be employed. In a first approach, FEC1 may employ a systematic encoding procedure, in which the input bits are a subset of the output bits. Thus, FEC1 decoding may be bypassed to obtain the original bits. In this first approach, FEC1 is not activated for ONUs with eFEC capability and the performance may not be limited by FEC2. In a second approach, FEC1 may employ a soft-decoding scheme to provide performance improvement. For example, FEC1 may implement a soft-decoding scheme selected by the standard ONUs.

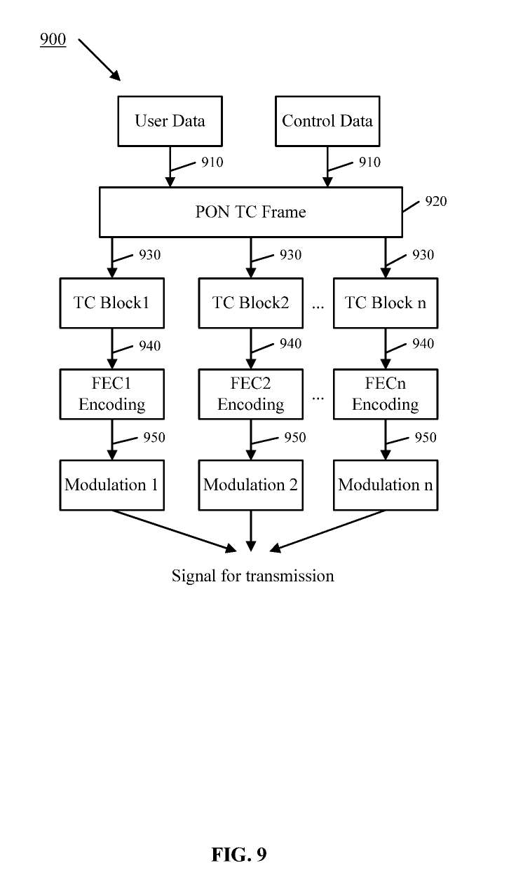

FIG. 9 is a schematic diagram of an embodiment of a parallel FEC encoding scheme 900. The scheme 900 may be employed by an OLT transmitter and/or an ONU transmitter in a PON, such as the PON 100. The scheme 900 may be applied to a PON PHY frame at the transmitter. At step 910, user data and control data are received. At step 920, a PON TC frame is generated from the received user data and control data. At step 930, the PON TC frame is divided into a plurality of TC blocks (e.g., TC block 1, TC block 2, . . . , TC block n). At step 940, each TC block is encoded by an FEC encoding scheme (e.g., FEC1 encoding, FEC2 encoding, . . . , FECn encoding). At step 950, after FEC encoding, each FEC-encoded data block is modulated by employing a modulation scheme (e.g., Modulation 1, Modulation 2, . . . , Modulation n) suitable for optical transmission. It should be noted that the TC blocks may be encoded by the same FEC encoding scheme, or may be encoded using different FEC encoding schemes. Similarly, the FEC-encoded data may be modulated by employing the same modulation scheme or different modulation schemes. For example, the FEC encoding scheme and/or the modulation scheme may be selected according to a particular optical link, such as an optical link of the ODN 130 in FIG. 1.

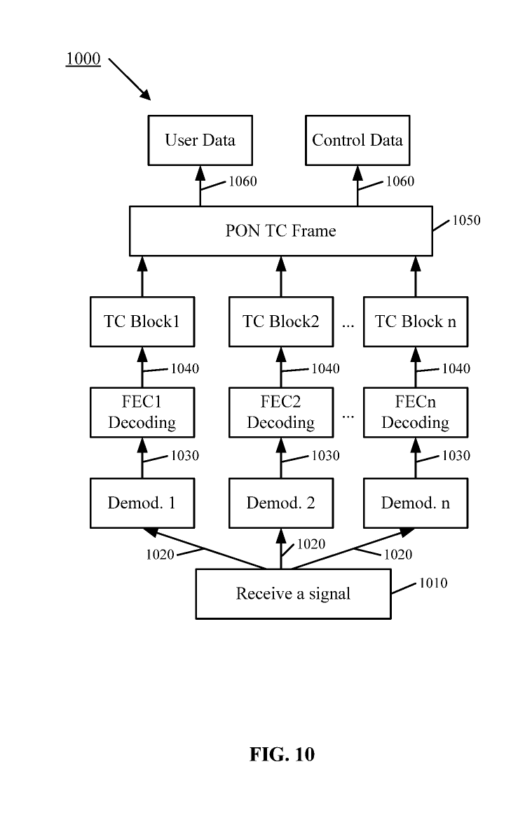

FIG. 10 is a schematic diagram of an embodiment of a parallel FEC decoding scheme 1000. The scheme 1000 may be employed by an OLT receiver and/or an ONU receiver in a PON, such as the PON 100. The scheme 1000 may be applied to a PON PHY signal received at the receiver. At step 1010, a signal is received by the receiver. For example, the signal may be transmitted by a transmitter employing the parallel FEC encoding scheme 900. The received signal may comprise a modulated signal in some examples. At step 1020, the received signal is divided into a plurality of signal blocks. At step 1030, each signal block is demodulated by employing a demodulation scheme (e.g., Demodulation 1, Demodulation 2, . . . , Demodulation n) to generate blocks of demodulated data. At step 1040, each block of demodulated data is decoded according to a FEC decoding scheme (e.g., FEC1 decoding, FEC2 decoding, . . . , FECn decoding) to produce a TC block. At step 1050, the TC blocks are assembled into a PON TC frame. At step 1060, the PON TC frame is separated into a user data portion and a control data portion. Similar to the scheme 900, the same FEC decoding scheme or different FEC decoding schemes may be applied to the demodulated data blocks at step 1040 and the same demodulation scheme or different demodulation schemes may be applied to the signal block at step 1020.

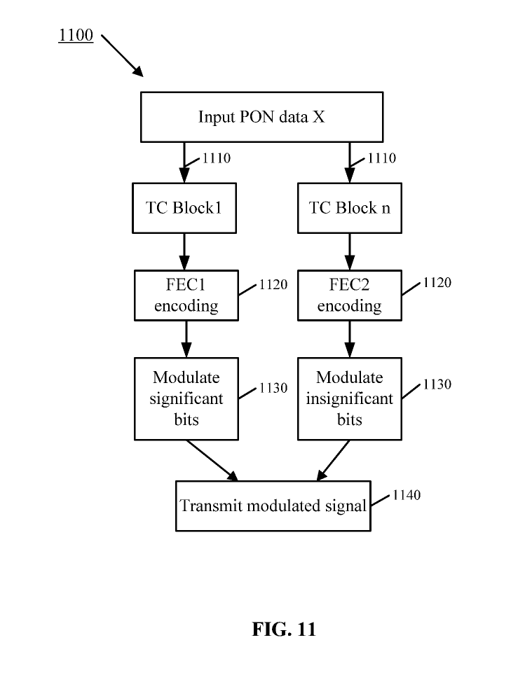

FIG. 11 is a schematic diagram illustrating an embodiment of a method 1100 for performing parallel FEC encoding. The method 1100 is implemented by an OLT transmitter and/or an ONU transmitter in a PON, such as the PON 100. The method 1100 employs similar mechanisms as described in the scheme 900. The method 1100 is implemented when generating PON PHY frames for transmission. At step 1110, input PON data, denoted as X, is divided into a TC block 1 and a TC block 2. At step 1120, the TC block 1 is encoded by an FEC1 scheme to produce an FEC 1-encoded block, and the TC block 2 is encoded by an FEC2 scheme to produce an FEC2-encoded block. At step 1130, the FEC1-encoded block is modulated as the significant bits of a pulse-amplitude modulation 4 (PAM4) signal, for example, and the FEC2-encoded block is modulated as the insignificant bits of the PAM4 signal. At step 1140, the PAM4 signal is transmitted. The PAM4 modulation is used merely as an example, and any suitable modulation could be used.

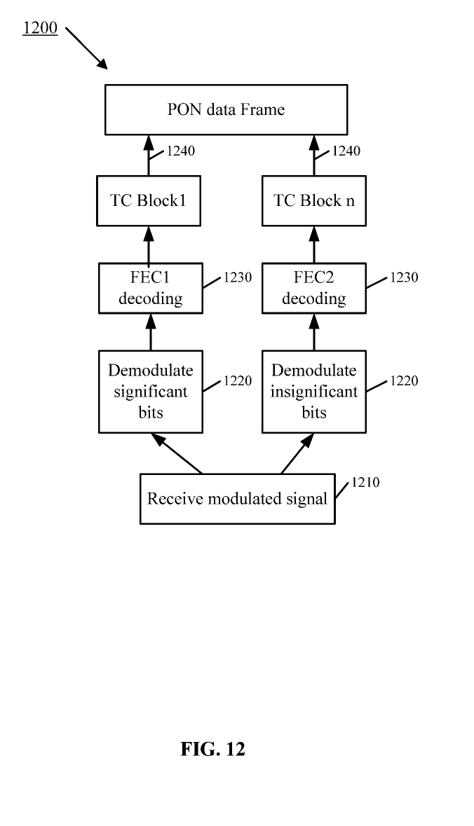

FIG. 12 is a schematic diagram illustrating an embodiment of a method 1200 for performing parallel FEC decoding. The method 1200 is implemented by an OLT receiver and/or an ONU receiver in a PON, such as the PON 100. The method 1200 employs similar mechanisms as described in the scheme 1000. The method 1200 begins at step 1210 when the receiver receives a modulated signal. For example, the modulated signal may be transmitted by a transmitter employing the scheme 900 and/or the method 1100. At step 1220, the significant bits of the received modulated signal and the insignificant bits of the received modulated signal are demodulated. At step 1230, the demodulated significant bits are decoded by employing an FEC1 decoding scheme to produce a TC block 1, and the demodulated insignificant bits are decoded by employing an FEC2 decoding scheme to produce a TC block 2. At step 1240, the TC block 1 and the TC block 2 are reassembled into a PON data frame.

In an embodiment, PAM4 modulation is employed for rate improvement. Other modulations could be used as well, for instance, QAM, OOK, QPSK, NRZ and so on. For example, in a PON, there are two types of ONUs: standard ONUs using OOK modulation with non-return-to-zero (NRZ) line code, and the enhanced ONUs using PAM4 modulation.

When FEC1 comprises rFEC, as specified by a PON standard, the standard ONUs may make decisions between the significant bits by performing FEC1 decoding, and thus no errors may result due to incompatibility. The enhanced ONUs may perform both FEC1 and FEC2 decoding to decode the PON data carried by the PAM4 signal. In addition, the enhanced ONUs may apply soft-decision coding to achieve a higher coding gain.

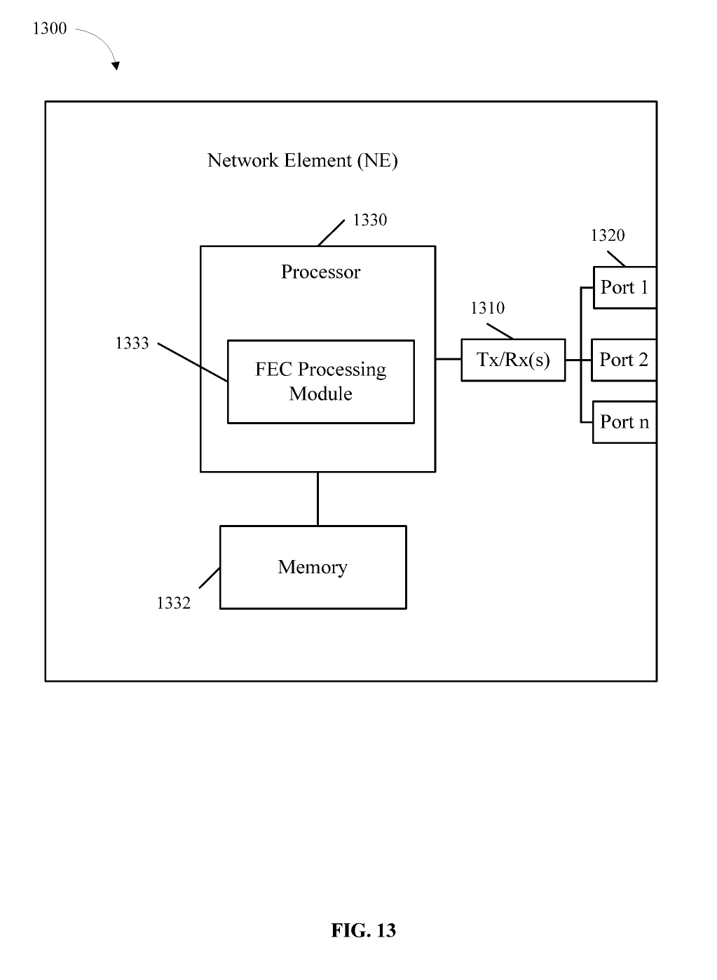

FIG. 13 is a schematic diagram of an embodiment of an NE 1300 acting as a node in a PON, such as the PON 100. For example, the NE 1300 may be configured to act as a transmitter, such as the transmitter 110, and/or a receiver, such as the receiver 120. The NE 1300 may be configured to implement and/or support a concatenated FEC coding and a parallel FEC coding, as described herein. NE 1300 may be implemented in a single node or the functionality of NE 1300 may be implemented in a plurality of nodes in a network. One skilled in the art will recognize that the term NE encompasses a broad range of devices of which NE 1300 is merely an example. NE 1300 is included for purposes of clarity of discussion, but is in no way meant to limit the application of the present disclosure to a particular NE embodiment or class of NE embodiments. At least some of the features/methods described in the disclosure may be implemented in a network apparatus or component such as an NE 1300. For instance, the features/methods in the disclosure may be implemented using hardware, firmware, and/or software installed to run on hardware. The NE 1300 may be any device that processes, stores, and/or forwards data frames through a network, e.g. a server, a client, a data source, etc. As shown in FIG. 13, the NE 1300 may comprise transceivers (Tx/Rx) 1310, which may be transmitters, receivers, or combinations thereof. Tx/Rxs 1310 may be coupled to a plurality of ports 1320 (e.g., upstream interfaces and/or downstream interfaces) for transmitting and/or receiving frames from other nodes. A processor 1330 may be coupled to the Tx/Rxs 1310 to process the frames and/or determine which nodes to send frames to processor 1330 may comprise one or more multi-core processors and/or memory devices 1332, which may function as data stores, buffers, etc. Processor 1330 may be implemented as a general processor or may be part of one or more application specific integrated circuits (ASICs) and/or digital signal processors (DSPs). Processor 1330 may comprise an FEC processing module 1333, which may perform methods 700, 800, 1100, and/or 1200, depending on the embodiment. The NE 1300 may comprises the transmitter 610 and the receiver 620 in FIG. 6. The NE 1300 may comprise parallel FEC encoding scheme 900 in FIG. 9 and decoding scheme 1000 in FIG. 10. In an alternative embodiment, the FEC processing module 1333 may be implemented as instructions stored in memory 1332, which may be executed by processor 1330, for example as a computer program product. In another alternative embodiment, the FEC processing module 1333 may be implemented on separate NEs.

It is understood that by programming and/or loading executable instructions to the NE 1300, at least one of the processor 1330, the FEC processing module 1333, ports 1320, Tx/Rxs 1310, and/or memory 1332 are changed, transforming the NE 1300 in part into a particular machine or apparatus, e.g., a multi-core forwarding architecture, having the novel functionality taught by the present disclosure. It is fundamental to the electrical engineering and software engineering arts that functionality that can be implemented by loading executable software into a computer can be converted to a hardware implementation by well-known design rules. Decisions between implementing a concept in software versus hardware typically hinge on considerations of stability of the design and numbers of units to be produced rather than any issues involved in translating from the software domain to the hardware domain. Generally, a design that is still subject to frequent change may be preferred to be implemented in software, because re-spinning a hardware implementation is more expensive than re-spinning a software design. Generally, a design that is stable that will be produced in large volume may be preferred to be implemented in hardware, for example in an ASIC, because for large production runs the hardware implementation may be less expensive than the software implementation. Often a design may be developed and tested in a software form and later transformed, by well-known design rules, to an equivalent hardware implementation in an application specific integrated circuit that hardwires the instructions of the software. In the same manner as a machine controlled by a new ASIC is a particular machine or apparatus, likewise a computer that has been programmed and/or loaded with executable instructions may be viewed as a particular machine or apparatus.

While several embodiments have been provided in the present disclosure, it may be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and may be made without departing from the spirit and scope disclosed herein.

What is claimed is:

1. An error correction method, comprising:
receiving an input data;
processing the input data with a first Forward Error Code (FEC) transformation;
processing the input data with a second FEC transformation; and
generating an output data including the first transformation and the second transformation.

2. The method according to claim 1, wherein the first and second FEC transformations comprise FEC encoding or FEC decoding transformations.

3. The method according to claim 1, wherein the first FEC transformation comprises a regular FEC (rFEC) transformation.

4. The method according to claim 1, wherein the second FEC transformation comprises an enhanced FEC (eFEC) transformation.

5. The method according to claim 1, with the first FEC transformation and the second FEC transformation comprising a concatenated processing.

6. The method according to claim 1, with the first FEC transformation and the second FEC transformation comprising a concatenated processing and with each data block being transformed by both the first FEC transformation and the second FEC transformation.

7. The method according to claim 1, with the first FEC transformation and the second FEC transformation comprising a parallel processing.

8. The method according to claim 1, with the first FEC transformation and the second FEC transformation comprising a parallel processing and with first data blocks transformed by the first FEC transformation being interleaved with second data blocks transformed by the second FEC transformation.

9. The method according to claim 1, wherein the first FEC transformation and the second FEC transformation are based on a link condition.

10. The method according to claim 1, further comprising processing the input data with at least a third FEC transformation.

11. A network device, comprising:
a transceiver configured to receive an input data; and
a processor coupled to the transceiver and configured to:
process the input data with a first Forward Error Code (FEC) transformation;
process the input data with a second FEC transformation; and
generate an output data including the first transformation and the second transformation.

12. The network device according to claim 11, wherein the first and second FEC transformations comprise FEC encoding or FEC decoding transformations.

13. The network device according to claim 11, wherein the first FEC transformation comprises a regular FEC (rFEC) transformation.

14. The network device according to claim 11, wherein the second FEC transformation comprises an enhanced FEC (eFEC) transformation.

15. The network device according to claim 11, wherein the first FEC transformation and the second FEC transformation comprise a concatenated processing.

16. The network device according to claim 11, with the first FEC transformation and the second FEC transformation comprising a concatenated processing and with each data block being transformed by both the first FEC transformation and the second FEC transformation.

17. The network device according to claim 11, wherein the first FEC transformation and the second FEC transformation comprise a parallel processing.

18. The network device according to claim 11, with the first FEC transformation and the second FEC transformation comprising a parallel processing and with first data blocks transformed by the first FEC transformation being interleaved with second data blocks transformed by the second FEC transformation.

19. The network device according to claim 11, wherein the first FEC transformation and the second FEC transformation are based on a link condition.

20. The network device according to claim 11, wherein the processor is configured to process the input data with at least a third FEC transformation.

21. A Passive Optical Network (PON), comprising:
a first network device, configured to:
generate an output data by encoding an input data with a first Forward Error Code (FEC) and with a second FEC; and
send the output data to a second network device; and
the second network device coupled to the first network device and configured to:
obtain the input data by decoding the output data with the first FEC and the second FEC.

22. The PON according to claim 21, with the first network device comprising an Optical Line Terminal (OLT), an Optical Network Unit (ONU), or an Optical Network Terminal (ONT).
